(19) United States
(12) Patent Application Publication
(10) Pub. No.: US 2025/0178550 A1
(43) Pub. Date: Jun. 5, 2025

(54) A VEHICLE POWER SUPPLY MANAGEMENT SYSTEM

(71) Applicant: Jonathan NASSIF, Peakhurst (AU)

(72) Inventor: Jonathan NASSIF, Peakhurst (AU)

(21) Appl. No.: 18/843,655

(22) PCT Filed: Mar. 9, 2023
(86) PCT No.: PCT/AU2023/050164

§ 371 Date: Sep. 3, 2024

(30) Foreign Application Priority Data
Mar. 9, 2022 (AU) 2022900569
Apr. 13, 2022 (AU) 2022900985
Aug. 16, 2022 (AU) 2022902318

(51) Int. Cl. B60R 16/033; G01R 31/36; G01R 31/392; H02J 7/00

(52) U.S. Cl. CPC B60R 16/033; G01R 31/3647; G01R 31/392; H02J 7/0013

(57) ABSTRACT

A vehicle power supply management system has a power supply comprising a plurality of battery cells and switching controlling electrical connection of the battery cells. The system is configured to measure an electrical parameter to determine a power consumption requirement and dynamically assign the battery cells to primary and auxiliary groups. The number of battery cells assigned to the auxiliary group depends on the power consumption requirement. During the power consumption requirement, the system controls the switching to electrically connect battery cells assigned to the auxiliary group to supply power for the power consumption requirement.

### FIELD OF THE INVENTION

This invention relates generally to a type of vehicle power supply management system which is designed to ensure that there is sufficient battery power supply for a vehicle power consumption requirement, such as crank starting.

### BACKGROUND OF THE INVENTION

A vehicle internal combustion engine is started using a starter motor which draws power from a battery power supply (typically a lead acid battery) during ignition.

However, the battery power supply may sometimes become too depleted (such as from vehicle system parasitic power draw) to supply sufficient power for the starter motor, thereby rendering the vehicle inoperable and requiring jumpstarting, towing or the like.

A vehicle may have other power consumption requirements such as for unlocking and opening doors, for example. Electric vehicles are sometimes known to become inaccessible if the batteries thereof become too depleted to operate the doors.

The present invention seeks to provide a vehicle power supply management system, which will overcome or substantially ameliorate at least some of the deficiencies of the prior art, or to at least provide an alternative.

It is to be understood that, if any prior art information is referred to herein, such reference does not constitute an admission that the information forms part of the common general knowledge in the art, in Australia or any other country.

### SUMMARY OF THE DISCLOSURE

There is provided herein a vehicle power supply management system comprising a power supply comprising a plurality of battery cells.

The system further comprises switching controlling electrical connection of the battery cells.

The system is configured to dynamically assign the battery cells to primary and auxiliary groups.

The system is further configured to measure an electrical parameter to determine a power consumption requirement and wherein the number of battery cells assigned to the auxiliary group depends on the power consumption requirement.

During the power consumption requirement, the system controls the switching to electrically connect battery cells assigned to the auxiliary group to supply power for the power consumption requirement.

As such, the present system ensures that the battery cells assigned to the auxiliary group always have sufficient charge to meet the determined power consumption requirement.

For example, for an internal combustion engine vehicle power consumption requirement for crank starting, the system may measure the electrical parameter during crank starting to determine a crank start power consumption requirement. As such, during crank starting, the system controls the switching to electronically connect the battery cells assigned to the auxiliary group to supply power to a starter motor to meet the determined crank starting power consumption requirement.

As such, the present system ensures that the battery cells assigned to the auxiliary group always have sufficient charge for crank starting.

In embodiments, the number of battery cells assigned to the auxiliary group may further depend on a configuration which may affect power consumption requirements during crank starting, such as engine size and engine fuel type. For example, during initial installation, the system may be configured with configuration settings for a 3 L diesel engine.

In further embodiments, the number of battery cells assigned to the auxiliary group further depends on a further measured parameter which may affect power consumption requirements during crank starting. One such measured parameter may be temperature wherein, for example, the system may be configured to add an additional battery cell to the auxiliary group for each 2° C. temperature drop beneath 20° C.

In further embodiments, the number of battery cells assigned to the auxiliary group may further depend on a calculated parameter which may affect power consumption requirements during crank starting. One such calculated parameter may be battery age on account of battery cell efficiency diminishing over time. Another such calculated parameter may be a time elapsed since a last crank start indicative of cold or warm crank starting.

In embodiments, the system may be configured to rotate assignment of the battery cells between the primary and auxiliary groups to spread duty cycles thereof and increased the longevity of the power supply. The battery cells may be reassigned after a certain number of crank starts or after a time period. In certain embodiments, the system may be configured to reserve at least one cell permanently for the auxiliary group which would therefore not suffer duty cycle degradation from use in the primary group.

During charging, the system may be configured for prioritising charging of the battery cells assigned to the auxiliary group. The system may measure a charge state of the battery cells assigned to the auxiliary group to control such prioritisation.

In embodiments, the system may be configured to detect crank starting such as by detecting current exceeding a threshold or voltage falling beneath a threshold.

Preferably the system is configured for switching in the battery cells of the auxiliary group in a short time period, such as less than 10 ms or even less than 5 ms so as to be able to meet initial current inrush requirements. In alternative embodiments, the power supply may be manually configured in a crank starting mode to switch in the battery cells assigned to the auxiliary group when required.

In some embodiments, the system is configured to measure the charge state of the battery cells assigned to the primary group to determine whether the battery cells from the auxiliary group are required. For example, if the charge state of the primary group is sufficient to meet the crank start power consumption requirement, the system may reserve the cells of the auxiliary group for later use.

In embodiments, present system takes the form of a portable vehicle battery comprising an internal controller and which can be installed in a vehicle in conventional manner.

For electric vehicles, the power consumption requirements may relate to retaining sufficient power to open and close the vehicle doors, to be able to drive a certain distance or to retain the vehicle in ‘limp’ mode for a certain duration.

Other aspects of the invention are also disclosed.

### BRIEF DESCRIPTION OF THE DRAWINGS

Notwithstanding any other forms which may fall within the scope of the present invention, preferred embodiments of the disclosure will now be described, by way of example only, with reference to the accompanying drawings in which:

FIG. 1 shows a block level system diagram of a vehicle power supply management system in accordance with an embodiment;

FIG. 2 shows exemplary current draw during crank starting; and

FIG. 3 shows exemplary processing by the system in accordance with an embodiment.

### DESCRIPTION OF EMBODIMENTS

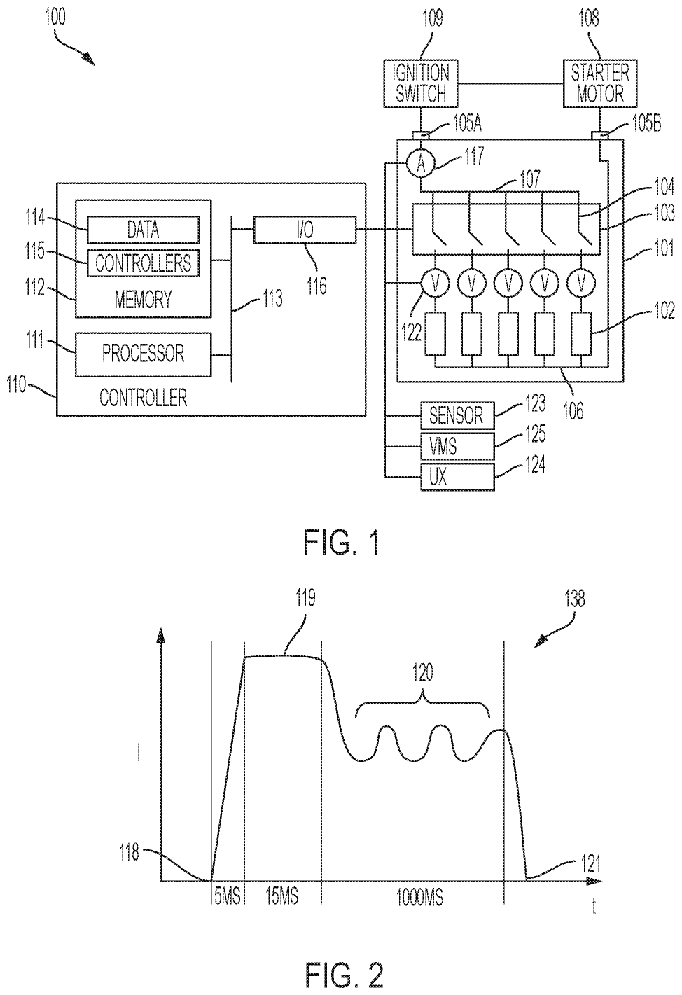

FIG. 1 shows a vehicle power supply management system 100 comprising a power supply 101 comprising a split cell arrangement of a plurality of individual battery cells 102.

The system 100 further comprises switching 103 electrically connecting the battery cells 102. The switching 103 may comprise an electrical switch 104 for each battery cell 102. The electrical switch 104 may be a high rated MOSFET switch or the like. The battery cells 102 may be lead acid based although other battery technologies are envisaged, including lithium-based battery cells 102.

According to the embodiment shown, the battery cells 102 are connected by the switching 103 in parallel. Each battery cell 102 may supply 12 V to be compatible with a vehicle electrical system.

In embodiments, the power supply 101 may be a physical portable battery having battery terminals 105 which may be installed on a vehicle and a conventional manner. The terminals 105 may comprise a positive battery terminal 105A and a negative battery terminal 105B.

As is shown, the negative battery terminal 105B may be connected to a common negative rail 106 of the battery cells 102. Furthermore, the positive battery terminal 105A may be connected to a common positive rail 107 interfacing the switching 103.

In alternative embodiments, the system 100 is integral installed in a vehicle, such as at the time of manufacture. In this embodiment, the battery cells 102 themselves may be able to be swapped out if necessary although the other componentry of the system 100 may remain installed.

The power supply 101 may be used to supply electrical power to a vehicle, including for a starter motor 108 thereof during crank starting. An ignition switch 109 may selectively interconnect the power supply 101 and the starter motor 108.

The system 100 is configured to measure an electrical parameter to determine a power consumption requirement.

Accordingly, the system 100 is configured to dynamically assign the battery cells 102 to primary and auxiliary groups. The number of battery cells 102 assigned to the auxiliary group 102 depends on the power consumption requirement.

As such, during the power consumption requirement, the system 100 is configured to control the switching 103 to electrically connect battery cells 102 assigned to the auxiliary group to supply power for the power consumption requirement.

In accordance with an embodiment, the power consumption requirement is a crank start power consumption requirement for an internal combustion engine vehicle, wherein the system 100 may measure the electrical parameter during crank starting to determine a crank start power consumption requirement.

As such, during crank starting, the system 100 controls the switching 103 to electronically connect the battery cells 102 assigned to the auxiliary group to supply power to a starter motor 108 to meet the determined crank starting power consumption requirement.

As such, the present system ensures that the battery cells assigned to the auxiliary group always have sufficient charge for crank starting.

In embodiments the system 100 may comprise a controller 110 which is configured for controlling the switching 103. The controller 110 comprises a processor 111 for processing digital data. The controller 110 may further comprise a memory device 112 operably interfacing the processor 111 via a system bus 113. A memory device 112 is configured for storing data 114 and computer program code instructions. In use, the processor 111 fetches these computer program code instructions and associated data 114 from the memory device 112 for interpretation and execution of the computational and control functionality described herein.

The computer program code instructions may be logically divided into a plurality of computer program code instruction controllers 115. For example, a controller 115 may be used for measuring the electrical parameter to determine the crank start power consumption requirement. Another controller 115 may be used for dynamically assigning the battery cells 102 between the primary and auxiliary groups. A further controller 115 may be used to control the switching 103.

The controller 110 may comprise an I/O interface 116 for interfacing the switching 103 and other peripherals. The I/O interface 116 may be a digital and/or analogue I/O interface 116.

In the embodiment where the power supply 101 is a physical portable battery, the battery may comprise the controller 110 internally installed therein. In this embodiment, the controller 110 may take the form of a small form factor ruggedised microprocessor device suited for such application, such as a field programmable gate array (FPGA) based controller.

The system 100 may comprise an ammeter 117 which is used by the controller 110 to measure the amperes drawn during crank starting. The controller 110 may use the current readings from the ammeter 117 to determine the crank start power consumption requirement.

FIG. 2 shows an exemplary current trend 138 during crank starting with the vertical axis thereof representing current and the horizontal axis representing time. When the ignition switch 109 is closed at point 118, inrush current over approximately 5 ms may take the current to a maximum plateau 119 of approximately 15 ms.

Once the starter motor 108 begins to turn, a series of current draw oscillations 120 at a frequency of approximately 2 Hz may be exhibited until the internal combustion engine is started whereafter the current falls back to zero at point 121.

In additional or alternative embodiments, the system 100 may comprise at least one voltmeter 122. The controller 110 may take voltage readings from the voltmeter 122 during crank starting to determine the crank start power consumption requirement. In embodiments shown, the system 100 comprises a voltmeter 122 interfacing each battery cell 102. In alternative embodiments, the system 100 comprises switching interfacing respective voltmeters 122 for the primary and auxiliary groups respectively. In this way, the system 100 is able to determine a charge state of the auxiliary or primary group as will be described in further detail below.

The data 112 may be configured with a lookup table which maps measured current and/or voltage against respective crank start power consumption requirements. Alternatively, the controller 110 may be configured to calculate the crank start power consumption requirements formulaically using the current and/or voltage.

In a preferred embodiment, the controller 110 uses both current and voltage to determine total power consumption during crank starting and therefore set the crank start power consumption requirement accordingly. The controller 110 may calculate the crank start power consumption requirement with a safety factor, such as an increase of 10% over and above the measured total power consumption.

In embodiments, the controller 110 may be configured to measure crank start power consumption over a plurality of crank starts to calculate the crank start power consumption requirement using a rolling average calculation. The rolling average calculation may be used to account for variability in power consumption requirements which may be affected over time by factors such as battery life, temperature and the like.

For example, during winter months wherein colder engines consume more power during crank starting, the rolling average may gradually increase the crank start power consumption requirement as the season cools into winter and, alternatively, gradually decrease the crank start power consumption requirement as the season warms into summer.

The data 114 may comprise an assignment table which records which battery cell 102 is assigned to which group. The assignment table is dynamically updated by the controllers 115 over time.

In embodiments, the number of battery cells 102 assigned to the auxiliary group further depends on a configuration setting which may affect power consumption requirements. For example, the configuration setting may comprise an engine size configuration setting wherein larger engines require greater power during crank starting. By way of further example, the configuration setting may comprise a fuel type wherein, for example, diesel engines require greater power during starting, including for coil preheating.

As such, for example, during initial configuration, the system 100 may be configured with configuration settings which are stored within the data 114 specifying that the power supply 110 is installed on a 3 L diesel engine. The aforedescribed lookup table which maps voltage and/or current to respective crank start power consumption requirements may further map according to these configuration settings. For example, the lookup table may comprise separate mappings for diesel engines as opposed to petrol engines.

In embodiments, the number of battery cells assigned to the auxiliary group further depends on a further measured parameter. With reference to FIG. 1, the system 100 may comprise a sensor 123. The controller 110 may read signals from the sensor 123 to determine the further measured parameter.

In embodiments, custom sensors 123 may be installed on a vehicle. In alternative embodiments, the controller 110 may operably interface a vehicle management system 125 including to read various sensor data therefrom. In a yet further embodiment wherein the power supply 101 is a portable battery, the requisite sensors (such as ambient air temperature sensors) may be integral installed therein.

In an embodiment, the sensor 123 is a thermometer as temperature can affect power consumption requirements during crank starting. As such, the controller 110 may dynamically assign more battery cells 102 to the auxiliary group in colder weather as compared to warmer weather.

The further measured parameter may be used to vary the number of battery cells 110 assigned to the auxiliary group according to the determined crank start power consumption requirement.

For example, for a particular vehicle wherein the controller 110 has determined that 10 battery cells 102 are to be reserved in the auxiliary group for crank starting, the controller 110 may be programmed to increase the number of battery cells 102 assigned to the auxiliary group by one battery cell 102 for each 2° C. drop in temperature beneath 20° C. As such, a 0° C., the controller 110 would have assigned an additional 10 battery cells 102 to the auxiliary group in addition to the 10 battery cells 102 already assigned to the auxiliary group according to the determined crank start power consumption requirement.

In embodiments, during initialisation (such as post manufacture or installation) the controller 110 may enter an initial calibration stage wherein these further measured parameter are instantiated by way of measurements using the associated sensors 123. Once these further measured parameters are calibrated, the controller 110 may store these measured parameters within memory for subsequent look up.

Periodically, the controller 110 may reinitialise these various measured parameters by taking further measurements. For example, some parameters may not require re-initialisation, such as engine capacity whereas others may, such as ambient temperature.

In embodiments, the number of battery cells assigned to the auxiliary group further depends on a calculated parameter which may affect power consumption requirements during crank starting.

One such calculated parameter may be battery age on account of efficiency of battery cells 102 deteriorating over time. For example, the controller 110 may be configured to add an additional battery cell 102 to the auxiliary group every six months since installation.

The controller 110 may interface a user interface 124 which may comprise a digital display and/or pushbuttons. The user interface 124 may be used to reset a timer at initial installation for the calculation of elapsed time.

In further embodiments, the calculated parameter is calculated as an elapsed time since a last crank start. For example, the controller 110 may be configured to reserve an additional five battery cells 102 for the auxiliary group if the vehicle was last started more than one hour ago. In other words, when the engine has recently been started and is therefore still currently warm, the starter motor 108 would have less power consumption requirements during crank starting as compared to had it not been started for some time.

As alluded to above, the number of battery cells 102 assigned to the auxiliary group according to the crank start power consumption requirement may be varied formulaically according to the measured and/or calculated parameters. Alternatively, the controller 110 may use the aforedescribed lookup table to calculate the variance of the number of battery cells 102 assigned to the auxiliary group according to the measured and/or calculator parameters.

In embodiments, the controller 110 is configured to rotate assignment of the battery cells between the primary and auxiliary groups.

For example, after a certain number of crank starts or after a certain time period (such as one month), the controller 110 may reassign five battery cells 105 from the auxiliary group to the primary group and correspondingly reassign a respective five battery cells 105 from the primary group to the auxiliary group. Such rotational assignment shares duty cycles between the battery cells 102, thereby increasing the longevity of the power supply 101.

However, in embodiments, the controller 110 may be configured for reserving at least one battery cell 102 for the auxiliary group which is never assigned to the primary group. This at least one reserved battery cell 102 would therefore not exhibit duty cycle degradation over time, thereby ensuring that at least one underutilised battery cell 102 remains with the auxiliary group.

In embodiments, the system 100 is configured to detect crank starting and to control the switching 103 responsively. For example, the controller 110 may use the ammeter 117 to detect when current draw exceeds a threshold indicative of crank starting. The controller 110 may reactively switch in the battery cells 102 from the auxiliary group, preferably within less than 5 ms so as to meet the maximum current draw 119 requirements shown in FIG. 2. Similarly, the controller 110 may use the at least one voltmeter 122 to detect the voltage drop beneath a threshold indicative of crank starting.

In alternative embodiments, the system be manually configurable in a crank starting mode and wherein the system is configured to control the switching to electrically connect the battery cells 102 assigned to the auxiliary group when the system 100 is in the crank starting mode.

For example, where the power supply 101 takes the form of a portable battery, the user interface 124 thereof may take the form of a toggle switch. During crank starting, the user may flick the toggle switch to configure the portable battery in the crank starting mode so that the battery cells 102 assigned to the auxiliary group are switched in for crank starting.

During charging of the power supply 101, the system 100 may be configured for controlling the switching 103 to prioritise charging of the battery cells 102 assigned to the auxiliary group. The system 100 may further be configured to measure a charge state of the battery cells 102 assigned to the auxiliary group.

For example, the controller 110 may be configured to detect charging wherein current or voltage determined by the ammeter 117 or at least one voltmeter 122 exceeds a threshold. For example, the controller 110 may detect charging when voltage detected by the at least one voltmeter exceeds 13 V.

The controller 110 may monitor the charge state of each battery cell 102 to determine the charge state thereof. For example, the controller 110 may determine that a measured voltage of less than 8 V is to be categorised as a depleted charge state. As such, when detecting depleted battery cells 102 assigned to the auxiliary group using the respective voltmeters 122 thereof, the controller 110 may control the switching 103 to firstly charge these depleted battery cells 102 until, for example, detecting a voltage rise beyond 12.5 V whereafter the other cells 102 of the primary group may be connected by the switching 103 for recharging.

In embodiments, the controller 110 is configured to measure the charge state of the battery cells 102 assigned to the primary group to determine whether to control the switching 103 to electrically connect the battery cells 102 assigned to the auxiliary group during crank in. For example, should the measured charge state of the battery cells 102 assigned to the primary group indicate that the measured charge state is sufficient to meet the crank start power consumption requirement, the controller 110 may be configured to not switching the battery cells 102 assigned to the auxiliary group.

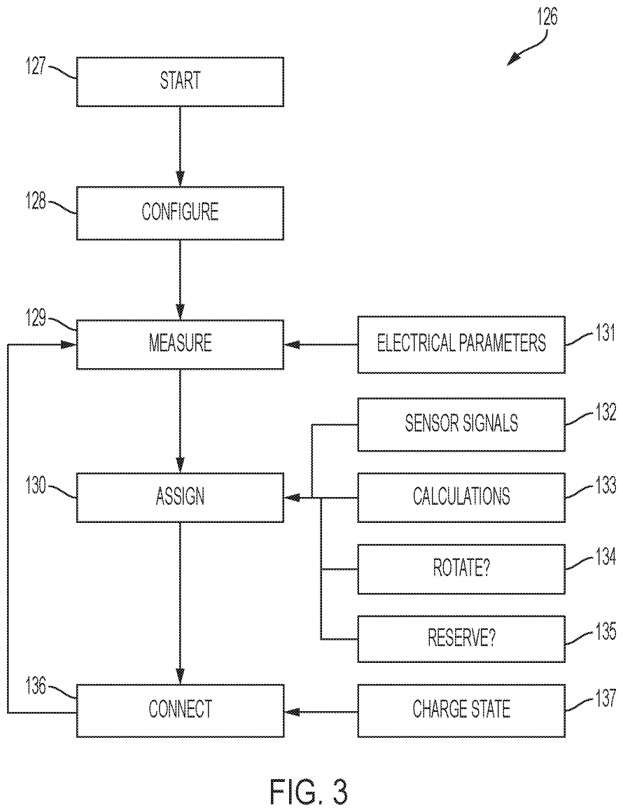

FIG. 3 shows exemplary processing 126 which may be implemented by the system 100 in relation to a crank start power consumption requirement. In embodiments, the processing 126 is implemented by the controller 110.

The processing starts at step 127. At step 128, the controller 110 may be configured with various configurations settings. These configuration settings may include the number of cells 120 of the power supply 110 for the assignment table in memory 112.

Furthermore, these configuration settings may comprise the aforedescribed configuration settings which may affect power consumption requirements during crank starting, such as engine size, fuel type and the like. As also alluded to above, these configuration settings may be used as part of the lookup table to map measure electrical parameters to respective crank start power consumption requirements.

At step 129, the controller 110 is configured to measure an electrical parameter 131 to determine the crank start power consumption requirements.

As alluded to above, the controller 110 may use the ammeter 117 to measure current draw during crank starting, the at least one voltmeter 122 to measure voltage during crank starting and preferably both current and voltage to measure actual power consumption.

The controller 110 may be configured to integrate the current draw (i.e., calculate the area under the current draw trend 138) to measure the total current draw over time between the start 118 of the crank starting at the end 121 of the crank starting. In other words, the controller 110 may be configured to accurately measure the amp-hours for the requisite power consumption requirements in accordance with the measured current.

The controller 110 may then store the determined crank start power consumption requirements within memory 112.

As alluded to above, the controller 112 may increase the crank start power consumption requirements with a safety factor, such as 10%.

At step 130, the controller 110 dynamically assigns battery cells 102 to the auxiliary group.

As is shown, at step 130, the controller 110 may further receive sensor signals 132 from the sensor 123 to adjust the number of battery cells 102 assigned to the auxiliary group. As alluded to above, the sensor 123 may comprise a temperature sensor wherein the controller 110 assigns more battery cells 102 to the auxiliary group at lower temperatures.

Also at step 130, the controller 130 may perform calculations 133 to adjust the number of battery cells 102 assigned to the auxiliary group. As alluded to above, these calculations 133 may be calculations that affect power consumption requirements during crank starting, such as battery age and elapsed time since the last crank start.

When assigning the battery cells 102 to the primary and auxiliary groups, the controller 120 may perform a rotational decision 134 to decide whether to rotate battery cells between the two groups. As alluded to above, after a certain number of crank starts (such as every 10 crank starts) or after a certain time period (such as every month), the controller 110 may reassign a certain number of battery cells 102 from the auxiliary group to the primary group and correspondingly reassign the same number of battery cells 102 from the primary group to the auxiliary group.

Also at step 130, the controller 110 makes a decision 135 as to whether to reserve certain battery cells 102 to the auxiliary group.

At step 136, during crank starting, the controller 110 controls the switching 103 to electrically connect battery cells assigned to the auxiliary group to supply power for the crank starting.

As alluded to above, the controller 110 may determine the charge state 137 of battery cells assigned to the primary group to decide if the battery cells 102 assigned to the auxiliary group are required for crank starting. In other words, if the charge state of the battery cells 102 assigned to the primary group is measure to be sufficient to meet the crank start power consumption requirements, the controller 103 may be programmed to not switch in the battery cells 102 assigned to the auxiliary group.

In a further embodiments, the power consumption requirements may relate to other types of vehicle power consumption requirements including for electric vehicles.

In this regard, the battery cells 102 may be used to power the electric motors of the electric vehicle. For example, the battery cells 102 assigned to the primary group may be used to power the electric motors of the vehicle whereas the battery cells 102 assigned to the auxiliary group may be kept in reserve to meet a measured power consumption requirement of the electric vehicle.

For example, the power consumption requirements may relate to retaining residual power within the auxiliary group to meet a measured door mechanism power consumption requirements to unlock and/or open the doors. In accordance with this embodiment, situations may be avoided wherein an electric vehicle cannot be opened due to a depleted battery, thereby requiring towing or the like.

In accordance with this example, during unlocking or opening of the doors of the vehicle, the controller 110 is configured for measuring the power consumption requirements (such as in terms of voltage and/or current) to open or unlock the doors of the vehicle. As such, the controller 110 may dynamically assign the battery cells 102 to the auxiliary group according to the determined power consumption requirements so that if the doors are required to be opened or unlocked despite the depletion of the battery cells 102 assigned to the primary group, the auxiliary group would have sufficient residual power for such.

In further embodiments, the power consumption requirements relates to a driveable distance power consumption requirement.

In accordance with this embodiment, the system 100 may measure power consumption during driving so as to determine the power consumption requirements required to drive the vehicle a certain distance.

For example, the controller 110 may measure power consumption requirements of the electric motors of the vehicle to determine the power consumption requirements for driving a distance of 50 km.

The power consumption requirements may be calculated by the controller 110 with reference to other parameters which may affect the driveable distance power consumption requirement, such as measured electrical circuit resistance, ambient temperature, drivetrain efficiency, vehicle mass, drag coefficient, rolling resistance, tyre pressure, air-conditioning system load, number of passengers and the like.

As such, the controller 110 may be configured to assign battery cells 102 to the auxiliary group depending on the measured power consumption requirements to drive a certain distance. The amount of battery cells 102 assigned to the auxiliary group may be adjusted according to these further measured parameters. For example, when sensing that the vehicle has four passengers, as opposed to passengers, the controller 110 may be configured to assign an additional two battery cells 102 to the auxiliary group to meet the measured power consumption requirements for four passengers.

The power consumption requirements may relate to a limp mode duration power consumption requirement wherein the controller 100 determines how much power is required to retain an electric vehicle in limp mode (i.e., wherein non-essential vehicle services such as air-conditioning is powered off by the vehicle management system 125) for a certain amount of time, such as one hour. In accordance with this embodiment, the controller 100 may measure electrical parameters of critical electrical services of the vehicle, such as vehicle management system power consumption requirements to dynamically determine how much power is required to maintain these critical electrical services for the specified duration.

Yet further power consumption requirements may relate to retaining sufficient power for other safety and essential vehicle systems including vehicle lighting, battery charging systems and the like.

In embodiments, the electric vehicle may comprise a high-voltage battery supply (such as a 350 V battery supply) for powering the electric motors thereof and an auxiliary 12 V battery. In this embodiment, the aforedescribed power supply 101 may take the form of the auxiliary 12 V battery. In this regard, controller 110 would take various electrical parameter measurements to dynamically assign sufficient battery cells 102 to the auxiliary group of the auxiliary 12 V battery 101 to ensure that the auxiliary 12 V battery 101 retains sufficient residual power to meet the relevant power consumption requirement. As such, even if the primary cells in the 12 volt battery were depleted, the auxiliary battery 101 would yet have sufficient power to control various safety and essential features of the vehicle, including door lock and opening mechanisms, the vehicle management system 125, systems which control the high voltage battery, lighting, battery charging systems, power steering and the like, including to power the assistance for a certain duration or distance as may be applicable.

As alluded to above, the controller 111 would take various electrical parameter measurements of these safety and essential systems (such as voltage, current draw and the like) to determine the power consumption requirements of the systems including for operating the systems for a certain duration or distance as the case may be.

Whereas in embodiments the controller 110 may take electrical parameter measurements to meet an individual power consumption requirement, in embodiments, the controller 110 may take electrical parameter measurements for a combination of power consumption requirements.

For example, during opening of the doors, the controller 110 may measure the current draw electrical parameters of the associated door unlocking mechanism. Furthermore, during cranking, the controller 111 may determine the power consumed by the starter motor 108 during cranking. As such, the controller 110 may be programmed to ensure sufficient cells 102 are assigned to the auxiliary group to meet the power consumption requirements of both the door unlocking and cranking.

The foregoing description, for purposes of explanation, used specific nomenclature to provide a thorough understanding of the invention. However, it will be apparent to one skilled in the art that specific details are not required in order to practise the invention. Thus, the foregoing descriptions of specific embodiments of the invention are presented for purposes of illustration and description. They are not intended to be exhaustive or to limit the invention to the precise forms disclosed as obviously many modifications and variations are possible in view of the above teachings. The embodiments were chosen and described in order to best explain the principles of the invention and its practical applications, thereby enabling others skilled in the art to best utilize the invention and various embodiments with various modifications as are suited to the particular use contemplated. It is intended that the following claims and their equivalents define the scope of the invention.

1. A vehicle power supply management system comprising:
a power supply comprising a plurality of battery cells,
switching controlling electrical connection of the battery cells, wherein the system is configured to:
measure an electrical parameter to determine a power consumption requirement;
dynamically assign the battery cells to primary and auxiliary groups, wherein the number of battery cells assigned to the auxiliary group depends on the power consumption requirement; and
during the power consumption requirement, control the switching to electrically connect battery cells assigned to the auxiliary group to supply power for the power consumption requirement, wherein the power consumption requirement is a crank start power consumption requirement and wherein the system is configured to measure crank start power consumption over a plurality of crank starts and to calculate the crank start power consumption requirement using a rolling average calculation.

2. (canceled)

3. The system as claimed in claim 21, further comprising an ammeter and wherein the system is configured to measure the crank start power consumption requirement using the ammeter during crank starting.

4. The system as claimed in claim 21, further comprising a voltmeter and wherein the system is configured to measure the crank start power consumption requirement using the voltmeter during crank starting.

5. (canceled)

6. The system as claimed in claim 1, wherein the number of battery cells assigned to the auxiliary group further depends on a configuration setting.

7. The system as claimed in claim 6, wherein the configuration setting comprises at least one of engine size and fuel type.

8. The system as claimed in claim 1, wherein the number of battery cells assigned to the auxiliary group further depends on a further measured parameter.

9. The system as claimed in claim 8, wherein the further measured parameter is temperature.

10. The system as claimed in claim 1, wherein the number of battery cells assigned to the auxiliary group further depends on a calculated parameter.

11. The system as claimed in claim 10, wherein the calculated parameter comprises at least one of battery age and elapsed time since a last crank start calculated parameters.

12. The system as claimed in claim 1, wherein the system is configured to rotate assignment of the battery cells between the primary and auxiliary groups.

13. The system as claimed in claim 12, wherein the system is configured to rotate assignment of the battery cells between the primary and auxiliary groups depending on a number of crank starts.

14. The system as claimed in claim 12, wherein the system is configured to rotate assignment of the battery cells between the primary and auxiliary groups depending on a time period.

15. The system as claimed in claim 12, wherein the system is configured to reserve at least one battery cell which is never assigned to the primary group.

16. The system as claimed in claim 1, wherein, during charging of the power supply, the system is configured for controlling the switching to prioritise charging of the battery cells assigned to the auxiliary group.

17. The system as claimed in claim 16, wherein the system is configured to measure a charge state of the battery cells assigned to the auxiliary group to prioritise charging of the battery cells assigned to the auxiliary group.

18. The system as claimed in claim 21, wherein the system is configured to detect crank starting and to control the switching responsively.

19. The system as claimed in claim 18, wherein the system is configured to detect crank starting by measuring current draw exceeding a threshold.

20. The system as claimed in claim 1, wherein the system is manually configurable in a crank starting mode and wherein the system is configured to control the switching to electrically connect the battery cells assigned to the auxiliary group when the system is in the crank starting mode.

21. The system as claimed in claim 1, wherein the system is configured to measure a charge state of battery cells assigned to the primary group to determine whether to control the switching to electrically connect the battery cells assigned to the auxiliary group to supply power for the power consumption requirement.

22. The system as claimed in claim 1, wherein the power supply is a portable battery and wherein the switching electrically connects the cells between terminals of the portable battery.

23. The system as claimed in claim 22, wherein the portable battery further comprises a controller configured to measure the crank start power consumption requirement and, during crank starting, control the switching to electrically connect battery cells assigned to the auxiliary group to supply power for the crank starting.

24. The system as claimed in claim 1, wherein the power consumption requirement is a door mechanism power consumption requirement.

25. The system as claimed in claim 1, wherein the power consumption requirement is a driveable distance power consumption requirement wherein the system is configured to measure an electric motor electrical parameter during driving to determine the driveable distance power consumption requirement to drive the vehicle a certain distance.

26. The system as claimed in claim 25, wherein the system is further configured to measure at least one of electrical circuit resistance, ambient temperature, drivetrain efficiency, vehicle mass, drag coefficient, rolling resistance, tyre pressure, air-conditioning system load and number of passengers to adjust the number of battery cells assigned to the auxiliary group.
